(19) United States
(12) Patent Application Publication
(10) Pub. No.: US 2009/0142584 A1
(43) Pub. Date: Jun. 4, 2009

(54) PROCESS FOR THE DEPOSITION OF METAL NANOPARTICLES BY PHYSICAL VAPOR DEPOSITION

(75) Inventors: Laurent Bedel, Quaix En Chartreuse (FR); Fabrice Emieux, Voreppe (FR); Sophie Mailley, Le Pin (FR); Anthony Taupeau, Pessac (FR)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: Commissariat A L'Energie Atomique

(21) Appl. No.: 12/276,653

(22) Filed: Nov. 24, 2008

(30) Foreign Application Priority Data
Nov. 30, 2007 (FR) 07/08374

(51) Int. Cl. B32B 5/16; C23C 14/34; C23C 14/35

(52) U.S. Cl. 428/328; 204/192.12; 204/192.14; 204/192.15

(57) ABSTRACT

The present invention relates to a process for the deposition of metal nanoparticles by physical vapor deposition at the surface of a substrate which may be heat-sensitive, at a pressure of the order of a few tens of pascals, and to the substrates obtained by implementing this process and to their applications.

### CROSS REFERENCE TO RELATED APPLICATIONS

This application claims priority from French Application No. 07 08374, filed Nov. 30, 2007.

### FIELD AND BACKGROUND OF THE INVENTION

The present invention relates to a process for the deposition of metal nanoparticles by physical vapor deposition at the surface of a substrate which may be heat-sensitive, at a pressure of the order of a few tens of pascals, and to the substrates obtained on implementing this process and to their applications.

The technical field of the invention may be generally defined as that of the preparation of a nanoparticulate coating at the surface of a heat-sensitive substrate or support.

These materials comprising a nanoparticulate coating are generally used in the fields of microelectronics (conductive, insulating or semi-conducting films), mechanical engineering (depositions of wear-resistant and corrosion-resistant layers), optics (radiation sensors) and especially catalysis, in particular for the protection of the environment.

The materials which are deposited in the form of particles at the nanometric scale have a greater reactivity than bulk materials. When they are applied at the surface of a substrate, these materials confer thereon specific properties which are essential for numerous applications, such as the deposition of catalyst for fuel cells or in order to catalyze chemical reactions, the manufacture of surfaces having specific optical properties or having an antibacterial property, and the like.

In this field, metals, such as platinum, rhodium, nickel or silver, form the subject of many studies.

Several types of processes which make it possible to cover the surface of a substrate with metal particles of this type have already been proposed. Two main routes are generally explored.

The first route consists in handling nanoparticles and in depositing them over a surface and involves, for example, techniques, such as impregnation and electrodeposition, which figure among the longest established processes.

The second, newer, route consists in forming the nanoparticles directly on the support to be coated. It comprises in particular Physical Vapor Deposition (PVD) processes and Chemical Vapor Deposition (CVD) processes.

Studies using CVD processes have shown the ability to immobilize nanometric particles on flat or porous substrates. In this respect, international application WO 2006/070130 reports, for example, the formation of nanoparticles of a metal or of an alloy of said metal by CVD starting from a source of precursors of organometallic type. The nanoparticles are then formed by thermal decomposition of the precursor at a high temperature, of the order of 200 to 300° C., indeed even more, according to a process in which the deposition time varies between a few minutes and 90 minutes. In “conventional” or “thermal” CVD, the temperature of the substrate provides the activation energy necessary for the heterogeneous reaction which is the cause of the growth of the deposited material. However, these high temperatures are not compatible with substrates to be covered which are heat-sensitive.

Physical vapor deposition (PVD) is a method for the deposition under vacuum of thin films. The main PVD methods are cathode sputtering and evaporation.

Cathode sputtering is a technique which allows the synthesis of several materials from the condensation on a substrate of a metal vapor resulting from a solid source (target material). The application of a potential difference between the target (acting as cathode) and the walls of the reactor within a rarified atmosphere makes possible the creation of a cold plasma, composed of electrons, ions, photons and neutrons in a ground or excited state. Under the effect of an electric field, the positive of the entities plasma are attracted by the cathode (target) and collide with the latter. They then pass on their amount of movement, thus bringing about the sputtering of the atoms of the target in the form of neutral particles which condense on the substrate (anode). The formation of the deposit layer on the substrate, generally in the form of a continuous film, takes place according to several mechanisms which depend on the forces of interaction between the substrate and the deposit. The discharge is self-maintained by the secondary electrons emitted from the target. This is because the latter, during inelastic collisions, transfer a portion of their kinetic energy as potential energy to the atoms of the residual gas (for example argon), which can become ionized.

Cathode sputtering deposition techniques exhibit the advantage of being able to coat substrates at ambient temperature. This technique is thus particularly well suited for heat-sensitive substrates. Industrially, the operating pressures are of the order of a pascal (Pa), in order to guarantee satisfactory rates of deposition. Thus it is that there has already been proposed, in particular by Ryan O-Hayre et al. (Journal of Power Sources, 2002, 109, 483-493), a process for the deposition of platinum on a copolymer resin based on sulfonated tetrafluoroethylene, known under the trade name Nafion®, by cathode sputtering at a pressure of 0.68 Pa for a power applied to the platinum target of the order of 100 W. For a very short deposition time (5 seconds), platinum microparticles appear on the Nafion® support and, beyond, a continuous film was subsequently formed. Other authors, Alvisi M. et al. (Surface & Coating Technology, 2005, 200, 1325-1329) have studied deposit layers of platinum on gas diffusion electrodes (GDL) at ambient temperature at a pressure of 0.28 Pa and for power densities of 1.23 W/cm². Under these conditions, the deposition time, which is not indicated by the authors, must be very short and does not make it possible to control the platinum content. A deposit layer produced under the same conditions results, on a flat support, in a continuous film; this is because the platinum particles are adjacent and some have already coalesced. Thus, by these processes, the deposit layers exist in the form of a continuous film, the step(s) of germination and of growth of the particles not making it possible to control their surface density as the coalescence between the particles takes place very rapidly.

Other authors, such as Hahn H. et al. (J. Appl. Phys., 1990, 67(2), 1113-1115), have used the magnetron cathode sputtering process to obtain powders with crystals of nanometric size. The magnetron cathode sputtering employs a magnetron device, which is composed of two permanent magnets of reverse polarity situated under the target. This technique makes it possible to increase the ion density in the vicinity of the target. This is because the magnets create a magnetic field B parallel to the surface of the target and orthogonal to the electric field E. The combination of these two fields gives rise to field lines which trap the secondary electrons. The Lorentz force induced brings about a helical motion of the electrons, thus increasing their trajectory and, for this reason, their ionization efficiency. The magnetron effect thus makes it possible to maintain the discharge for lower operating pressures, consequently improving the quality of the coatings obtained. The authors Hahn H. et al. indicate, however, that the use of a high pressure, that is to say of between 100 Pa and 1000 Pa, is necessary in order to be able to obtain particles of this type by this process. The measurement of the size of the crystallites obtained by this process was performed by x-ray diffractometry (XRD) but the authors do not report any observation of nanoparticles. According to this process, higher power densities were used (of the order of 25 W/cm²), which has the disadvantage of resulting in rapid warming of the substrate, which is incompatible with heat-sensitive substrates. Furthermore, within the pressure ranges used, the particles generated during the process are not adherent as they are collected by thermophoresis on a finger cooled with liquid nitrogen inside a reactor.

Thus it is, in order to overcome all these disadvantages and to provide for a process for the deposition of nanoparticles which is compatible with the possible use of heat-sensitive substrates, that the inventors have developed that which forms the subject matter of the present invention.

### SUMMARY OF THE INVENTION

Specifically, the inventors set themselves the aim of providing for a novel process for the deposition of nanoparticles at the surface of a substrate by physical vapor deposition which is easy to implement, which is suited to the use of heat-sensitive substrates, if desired, and which makes it possible to control the formation (size) and the distribution of the nanoparticles on the substrate.

Within the meaning of the present invention, the word “nanoparticle” defines particles which are isolated from one another and which exhibit a mean size of less than or equal to 20 nm. The size of the particles is measured by image analysis from photographs taken by SEM. These photographs are subsequently binarized and analyzed. The mean size is the arithmetic mean of the size of all the particles visible in the binarized photographs.

These aims are achieved by the process which forms the subject matter of the present invention and which will be described below.

A subject matter of the present invention is thus a process for the deposition of metal nanoparticles by physical vapor deposition, said process comprising at least one step of cathode sputtering of a target metal material in the presence of a neutral gas at the surface of a substrate, wherein said step of cathode sputtering is carried out in a chamber maintained at a pressure of 15 to 60 Pa, for a time of less than 20 seconds.

This is because the inventors have found that, when the pressure is greater than 60 Pa, discharge is less stable and few or no nanoparticles are deposited. Conversely, when the pressure is less than 15 Pa, a continuous film or the equivalent of coalesced particles is obtained and it is not possible to control the surface density of the nanoparticles.

Furthermore, for deposition times of greater than 20 seconds, the nanoparticles begin to coalesce to result in a thin film.

Preferably, the cathode sputtering step is a magnetron cathode sputtering.

By virtue of the process in accordance with the invention, it is possible to deposit, on the surface of the substrate, metal nanoparticles having a controlled mean size of between 2 and 20 nm approximately. The density of the nanoparticles at the surface of the substrate is controlled by the pressure and the deposition time. It is thus possible to obtain deposit layers of noncoalescent metal particles.

According to a preferred embodiment of the invention, the deposition time is between 2 and 20 seconds approximately.

During the sputtering step, the pressure within the chamber is preferably maintained at a value ranging from 20 to 40 Pa approximately, preferentially from 30 Pa to 40 Pa approximately.

According to a preferred embodiment of the invention, the sputtering step is carried out with a discharge power density on the metal target of between 0.2 W/cm² and 5 W/cm² inclusive and preferably between 0.5 and 1 W/cm² inclusive, more preferably 1 W/cm².

According to an advantageous embodiment of the invention, the neutral gas used during the sputtering step is chosen from rare gases and their mixtures. The rare gases (also known as noble gases or inert gases) correspond to the elements which form the eighth and final group of the Periodic Table of the Elements. This group comprises helium, neon, argon, krypton, xenon and radon. Among these rare gases, argon is very particularly preferred.

According to the process in accordance with the present invention, the sputtering step is carried out at a low temperature, that is to say at a temperature of the substrate of less than or equal to 100° C., this temperature being very obviously adjusted according to the nature of the substrate. Preferably, the sputtering step is carried out at ambient temperature.

This is an additional advantage of the process in accordance with the invention by virtue of which it is possible to operate on heat-sensitive substrates. According to the invention, a heat-sensitive substrate is a substrate which decomposes at low temperature (less than 150° C.).

The substrate on which the deposition of the nanoparticles is carried out can be both a porous substrate and a dense substrate which is optionally heat-sensitive. These substrates are as varied as glass, silicon, metals, steels, ceramics, such as alumina, ceria and zirconia, fabrics, zeolites, polymers, and the like.

Within the deposition chamber, the distance between the target and the substrate is preferably between 20 and 100 mm inclusive and more preferably still between 40 and 60 mm inclusive.

The nature of the metals constituting the metal target is not critical. They can in particular be chosen as a function of the properties which it is desired to confer on the substrate on which they will be deposited. Mention may be made, for example, among the metals which may constitute the metal target, of platinum, silver, gold, nickel, palladium, copper, rhodium, iridium, ruthenium, chromium, molybdenum and their mixtures.

According to the invention, the process can comprise several successive steps of depositions of nanoparticles using metal targets which are different in nature. It is possible to successively deposit, on the surface of the same substrate, nanoparticles of different metals.

In a particularly advantageous embodiment of the process of the invention, the substrate passes through the deposition chamber at a rate of forward progression such that the deposition time is less than 20 seconds, preferably between 2 and 10 seconds.

This process is also known as “forwardly progressing” deposition process. It makes it possible to cover large surface areas. In this process, the deposition time is controlled by the control of the rate of forward progression of the substrate to be covered in the deposition chamber, more specifically by the control of the rate of forward progression of the substrate in front of the metal target(s), which for their part are held stationary.

Another subject matter of the invention is the substrate capable of being obtained by the implementation of the process in accordance with the invention and as defined above, which is composed of a solid support comprising at least one surface on which is present a layer of noncoalescent metal nanoparticles, said nanoparticles having a mean size of less than or equal to 20 nm.

According to an advantageous embodiment, the mean size of the metal particles is between 2 and 10 nm inclusive.

The density of the metal nanoparticles on the surface of the substrate is preferably between 200 and 50 000 nanoparticles/μm² and more preferably still between 500 and 30 000 nanoparticles/μm².

Finally, these nanoparticles can advantageously be covered with a thin film preferably made of polymer or of a metal material or of ceramic, such as a carbide or a nitride or an oxide of a metal, for example silicon carbide, tungsten carbide, boron carbide, zirconium carbide, boron nitride, aluminum nitride, silicon nitride, titanium nitride, silicon oxide and zirconium oxide, but which can also be of an organic material. This film can be deposited by spraying, by painting, by dipping or else by any other suitable technique. The presence of this film makes it possible to encapsulate the deposit layer of the nanoparticles and thus to protect its surface. The film can also contribute a further role or improve a role already existing in the deposit layer, such as, for example, proton conductivity, absorption of radiation, and the like.

Due to the chemical nature of the metal nanoparticles deposited at their surface, the substrates thus prepared can exhibit a wide variety of applications.

Thus, when the surface of the substrate comprises silver nanoparticles, said substrate has antibacterial properties.

Another subject matter of the present invention is thus the use of a substrate as defined above, in which the metal nanoparticles are silver nanoparticles, as antibacterial substrate.

These substrates can also act as electrode material for a fuel cell.

Finally, when the metal nanoparticles are semiconducting, the substrate can be used as photo-voltaic material.

### BRIEF DESCRIPTION OF THE DRAWINGS

In addition to the preceding provisions, the invention also comprises other provisions which will emerge from the description which will follow, which refers to examples of the deposition of platinum nanoparticles on silicon supports or on gas diffusion electrodes and of the deposition of silver particles on a Nafion® support, and to the appended FIGS. 1 to 3, in which:

FIG. 1 is a scanning electron microscopy (SEM) photograph, with a magnification ×5.10⁵, of a silicon substrate, the surface of which has been covered with platinum nanoparticles according to the process in accordance with the invention;

FIG. 2 is a scanning electron microscopy (SEM) photograph, with a magnification ×5.10⁵, of a gas diffusion electrode, the surface of which has been covered with platinum nanoparticles according to the process in accordance with the invention;

FIG. 3 is a scanning electron microscopy (SEM) photograph, with a magnification ×2.10⁵, of a Nafion® substrate, the surface of which has been covered with silver nanoparticles according to the process in accordance with the invention;

FIG. 4 is a scanning electron microscopy (SEM) photograph, with a magnification ×5.10⁵, of a silicon substrate, the surface of which has been covered with platinum nanoparticles by the “forwardly progressing” process according to the invention;

FIG. 5 is a scanning electron microscopy (SEM) photograph, with a magnification ×2.10⁵, of a silicon substrate, the surface of which has been covered with silver nanoparticles by a process in which the pressure of the chamber was 10 Pa; and

FIG. 6 is a binarized image taken by SEM-FEG (field emission gun) with a magnification ×500 000 of a substrate made of carbon cloth, the surface of which has been covered with platinum nanoparticles by the process according to the invention.

However, it should be understood that these examples are given only purely by way of illustration of the invention and do not in any way limit the invention.

### EXAMPLES

In the exemplary embodiments which will be described below, the deposit layers were produced using a PVD device produced in the laboratory comprising, in a standard fashion in a chamber, the target and the substrate and also a magnetron connected to a power source.

### Example 1

### Preparation of Platinum Nanoparticles on a Silicon Substrate

The objective of this example is to demonstrate that the process in accordance with the present invention makes it possible to prepare platinum nanoparticles having a particulate size, that is to say a mean particle size, of approximately 2-3 nm.

Three depositions of platinum nanoparticles on a silicon substrate were carried out. The depositions were carried out from the pulsed current magnetron sputtering of a platinum (99.99% purity) target in the presence of an argon atmosphere. The operating conditions are combined below:

| | |
|---|---|
| Pressure of the chamber: | 30 Pa |
| Power density of the discharge on | 1 W/cm² |
| the target: | |
| Characteristics of the pulses: | |
| Frequency: | 70 kHz |
| Reverse time of the | 4 μs |
| polarization | |
| Dimensions of the platinum target | 210 × 90 mm² |
| Dimensions of the silicon | 50 × 50 mm² |
| substrate | |
| Substrate-target distance | 40 mm |
| Deposition time | 3 s, 5 s and 7 s |
| Gas | argon |
| Temperature | ambient |

For each of the three deposition times, the density of the deposition of the nanoparticles on the substrate was as follows:
Deposition time of 3 s:
   15 000 nanoparticles/μm² approximately.
Deposition time of 5 s:
   24 000 nanoparticles/μm² approximately.
Deposition time of 7 s:
   30 000 nanoparticles/μm² approximately.

These results show that the density of nanoparticles and the surface fraction are proportional to the deposition time.

The substrate corresponding to the deposition time=5 s was characterized by scanning electron microscopy as represented in the appended FIG. 1 (magnification ×5.10⁵). In this figure, platinum nanoparticles having a mean size in the vicinity of 2-3 nm with a particulate density of approximately 24 000/μm² and a surface fraction in the vicinity of 25% are observed, which clearly demonstrates that a continuous film is not obtained.

### Example 2

### Preparation of Platinum Nanoparticles on a Diffusion Layer (GDL)

The process for the deposition of platinum particles described above in example 1 was also repeated on a diffusion layer (gas diffusion electrode: GDL). The operating conditions are combined below:

| | |
|---|---|
| Pressure of the chamber: | 30 Pa |
| Power density of the discharge on | 1.5 W/cm² |
| the target: | |
| Characteristics of the pulses: | |
| Frequency: | 70 kHz |
| Reverse time of the | 4 μs |
| polarization | |
| Dimensions of the platinum target | 210 × 90 mm² |
| Nature of the GDL (substrate) | E-Tek ® r |
| sold by BASF | |
| Dimensions of the GDL | 50 × 50 mm² |
| Substrate-target distance | 40 mm |
| Deposition time | 5 s |
| Gas | argon |
| Temperature | ambient |

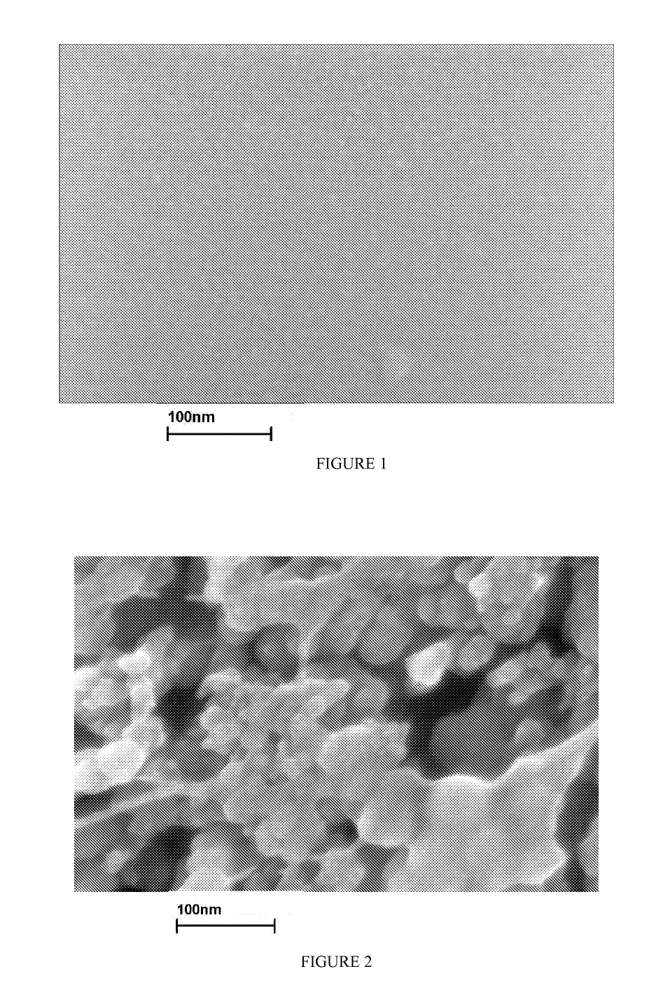

FIG. 2 is a scanning electron microscopy photograph (magnification ×5.10⁵) of the substrate thus obtained.

In this figure, the formation of platinum nanoparticles with a mean size in the vicinity of 2-3 nm is observed.

This deposit layer was subsequently covered by spraying with a Nafion® film with a thickness of approximately 100 nm in order to provide the proton conductivity of the electrode, as during the standard preparation of a fuel cell electrode.

### Example 3

### Preparation of Silver Nanoparticles on a Nafion® Substrate

The process for the deposition of platinum particles described above in example 1 was also repeated in order to produce silver particles (silver target with a purity of 99.99%) on a Nafion® substrate. The operating conditions are combined below:

| | |
|---|---|
| Pressure of the chamber: | 40 Pa |
| Power density of the discharge on | 1 W/cm² |
| the target: | |
| Characteristics of the pulses: | |
| Frequency: | 100 kHz |
| Reverse time of the | 2 μs |
| polarization | |
| Dimensions of the silver target | 210 × 90 mm² |
| Dimensions of the Nafion ® | 50 × 50 mm² |
| substrate | |
| Substrate-target distance | 40 mm |
| Deposition time | 5 s |
| Gas | argon |
| Temperature | ambient |

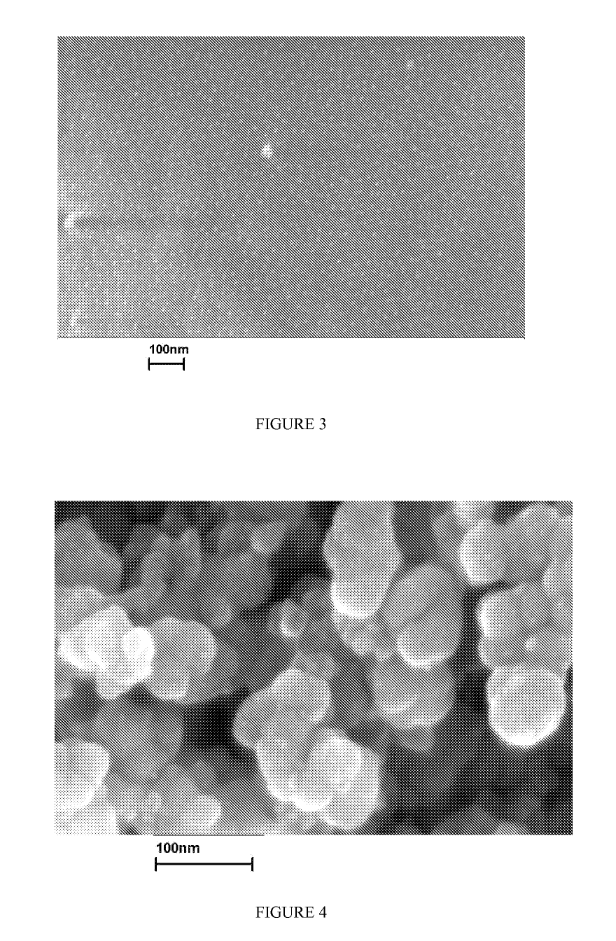

The formation of the nanoparticles was observed with a scanning electron microscope equipped with a field emission gun (SEM-FEG). FIG. 3 is a photograph taken with a magnification ×2.10⁵ of the substrate thus obtained.

In this figure, the formation of silver nanoparticles with a mean size of 10 nm is observed. It may be observed that these particles are uniformly distributed without aggregation and no decomposition of the Nafion® is observed at the surface. The surface density and the density of the nanoparticles are 17% and 2700 particles/μm² respectively.

### Example 4

### Deposition of Platinum Nanoparticles on a Silicon Substrate by the “Forwardly Progressing” Deposition Process

A deposition of platinum nanoparticles on a silicon substrate was carried out. The deposition was carried out by pulsed current magnetron sputtering of a platinum (99.99% purity) target under an argon atmosphere.

The substrate had a rate of forward progression of 0.6 m/min in front of the platinum target, which was kept stationary.

The operating conditions are combined below:

| | |
|---|---|
| Pressure of the chamber: | 30 Pa |
| Power density of the discharge on | 1 W · cm⁻², |
| the target: | |
| Characteristics of the pulses: | |
| Frequency: | 100 kHz |
| Reverse time of the | 2 μs |
| polarization | |
| Dimensions of the target | 210 × 90 mm² |
| Dimensions of the silicon | 15 × 15 cm² |
| substrate | |
| Target-substrate distance | 40 mm |
| Rate of forward progression | 0.6 m/min⁻¹ |
| Gas | argon |
| Temperature | ambient |

The formation of the platinum nanoparticles on the silicon substrate was observed with a scanning electron microscope equipped with a field emission gun (SEM-FEG).

FIG. 4 is a photograph taken with a magnification ×5.10⁵ of the surface of the substrate thus obtained.

In FIG. 4, the formation of platinum nanoparticles with a mean size of less than 5 nm is observed.

It may be observed that these nanoparticles are uniformly distributed without coalescence or aggregation.

### Example 5

### Deposition of Platinum Nanoparticles on a Substrate Composed of a Carbon Cloth

The deposition of the platinum nanoparticles on the substrate composed of a carbon cloth was carried out under the same conditions as in example 1, with a deposition time of 5 seconds.

The formation of the platinum nanoparticles was examined by scanning electron miscroscopy-FEG.

FIG. 6 represents the binarized image obtained at a magnification of ×780 000.

It is seen, in FIG. 6, that the platinum nanoparticles have a mean size of approximately 3 nm with a particle density of approximately 15 000 nanoparticles/μm², which clearly demonstrates that a continuous film was not obtained.

### Comparative Example

### Deposition of Silver Nanoparticles on a Silicon Substrate at a Pressure of the Chamber of 10 Pa

Silver nanoparticles were deposited on a silicon substrate. The deposition was carried out by pulsed current magnetron sputtering of a silver (99.99% purity) target under an argon atmosphere.

The operating conditions are combined below:

| | |
|---|---|
| Pressure of the chamber: | 10 Pa |
| Power density of the discharge on | 0.5 W · cm⁻² |
| the target: | |
| Characteristics of the pulses: | |
| Frequency: | 100 kHz |
| Reverse time of the | 2 μs |
| polarization | |
| Dimensions of the target | 210 × 90 mm² |
| Dimensions of the silicon | 5 × 5 cm² |
| substrate | |
| Target-substrate distance | 40 mm |
| Deposition time | 4 s |
| Gas | argon |
| Temperature | ambient |

The operating conditions used in this example correspond to those of the process of the invention except for the pressure, which is 10 Pa and not 15 to 60 Pa as in the process of the invention.

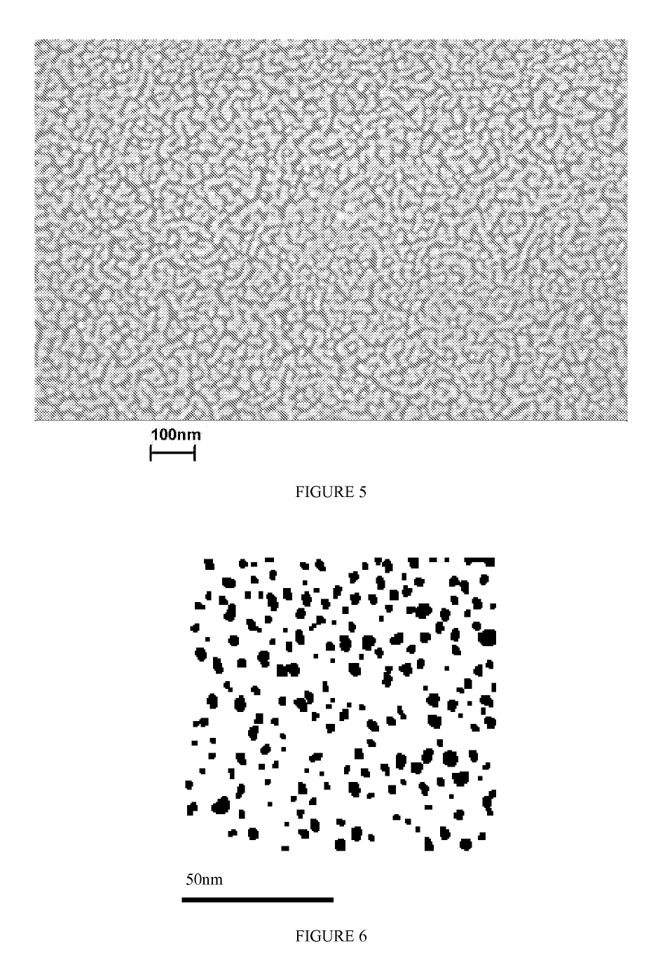

FIG. 5 is a scanning electron microscopy photograph (magnification ×2.10⁵) of the substrate thus obtained.

It is seen from FIG. 5 that the silver nanoparticles have coalesced to form a film at the surface of the substrate.

What is claimed is:

1. A process for the deposition of metal nanoparticles by physical vapor deposition, said process comprising at least one step of cathode sputtering of a target metal material in the presence of a neutral gas at the surface of a substrate, wherein said step of cathode sputtering is carried out in a chamber maintained at a pressure of 15 to 60 Pa, for a time of less than 20 seconds.

2. The process as claimed in claim 1, wherein the cathode sputtering step is a magnetron cathode sputtering.

3. The process as claimed in claim 1, wherein the deposition time is between 2 and 20 seconds.

4. The process as claimed in claim 1, wherein, during the sputtering step, the pressure within the chamber is maintained at a value ranging from 20 Pa to 40 Pa.

5. The process as claimed in claim 1, wherein the sputtering step is carried out with a discharge power density on the metal target of between 0.2 W/cm² and 5 W/cm² inclusive.

6. The process as claimed in claim 5, wherein the sputtering step is carried out with a discharge power density on the metal target of 1 W/cm².

7. The process as claimed in claim 1, wherein the neutral gas used during the sputtering step is chosen from rare gases and their mixtures.

8. The process as claimed in claim 7, wherein the rare gas used during the sputtering step is argon.

9. The process as claimed in claim 1, wherein the sputtering step is carried out at a temperature of the substrate of less than or equal to 100° C.

10. The process as claimed in claim 9, wherein the sputtering step is carried out at ambient temperature.

11. The process as claimed in claim 1, wherein the substrate is chosen from glass, silicon, metals, steels, ceramics, such as alumina, ceria and zirconia, fabrics, zeolites and polymers.

12. The process as claimed in claim 1, wherein, within the deposition chamber, the distance between the target and the substrate is between 20 and 100 mm inclusive.

13. The process as claimed in claim 12, wherein, within the deposition chamber, the distance between the target and the substrate is between 40 and 60 mm inclusive.

14. The process as claimed in claim 1, wherein the metals constituting the metal target are chosen from platinum, silver, gold, nickel, palladium, copper, rhodium, iridium, ruthenium, chromium, molybdenum and their mixtures.

15. The process as claimed in claim 1, which comprises several successive steps of deposition of nanoparticles, said deposition steps using metal targets which are different in nature.

16. The process as claimed in claim 1, wherein the substrate passes through the deposition chamber at a rate of forward progression such that the deposition time is between 2 and 20 s.

17. A substrate capable of being obtained by the implementation of the process as defined in claim 1, which is composed of a solid support comprising at least one surface on which is present a layer of noncoalescent metal nanoparticles, said nanoparticles having a mean size of less than or equal to 20 nm.

18. The substrate as claimed in claim 17, wherein the size of the nanoparticles is between 2 and 10 nm inclusive.

19. The substrate as claimed in claim 17, wherein the density of the metal nanoparticles on the surface of the substrate is between 200 and 50 000 nanoparticles/μm².

20. The substrate as claimed in claim 19, wherein the density of the metal nanoparticles on the surface of the substrate is between 500 and 30 000 nanoparticles/μm².

21. The substrate as claimed in claim 17, wherein the nanoparticles are covered with a thin film.

22. The substrate as claimed in claim 20, wherein the thin film is a film of polymer or of a metal material or of ceramic.

23. An antibacterial substrate comprising the substrate as defined in claim 17, and in which the metal nanoparticles are silver nanoparticles.

24. A fuel cell comprising the substrate as defined in claim 17.

25. A photovoltaic material comprising the substrate as defined in claim 17, and in which the metal nanoparticles are semiconducting.
